(19) United States
(12) Patent Application Publication
(10) Pub. No.: US 2012/0228663 A1
(43) Pub. Date: Sep. 13, 2012

(54) Optoelectronic Component Having a Semiconductor Body, an Insulating Layer, and a Planar Conductor Structure, and Method for the Production thereof

(75) Inventors: Karl Weidner, Munchen (DE); Ralph Wirth, Lappersdorf (DE); Axel Kaltenbacher, Mintraching (DE); Walter Wegleiter, Nittendorf (DE)

(73) Assignee: OSRAM Opto Semiconductors GmbH, Regensburg (DE)

(21) Appl. No.: 13/394,058

(22) PCT Filed: Aug. 5, 2010
(86) PCT No.: PCT/EP10/61443

§ 371 Date: May 16, 2012

(30) Foreign Application Priority Data
Sep. 3, 2009 (DE) 10 2009 039 890.2

(51) Int. Cl. H01L 33/62

(52) U.S. Cl. 257/99; 438/22; 257/E33.066

(57) ABSTRACT

An optoelectronic component comprising at least one semiconductor body having a radiation exit side, said semiconductor body being arranged by a side lying opposite the radiation exit side on a substrate, wherein at least one electrical connection region, on which a metallization bump is arranged, is arranged on the radiation exit side, the semiconductor body is at least partly provided with an insulating layer, wherein the metallization bump projects beyond the insulating layer, and at least one planar conductor structure is arranged on the insulating layer for the purpose of making contact with the semiconductor body in planar fashion, said conductor structure being electrically conductively connected to the electrical connection region by the metallization bump.

Optoelectronic component having a semiconductor body, an insulating layer, and a planar conductor structure, and method for the production thereof

This patent application claims the priority of German patent application 10 2009 039 890.2, the disclosure content of which is hereby incorporated by reference.

The present invention relates to an optoelectronic component comprising a semiconductor body, an insulating layer and a planar conductor structure for making contact with the semiconductor body in planar fashion. Furthermore, the invention relates to a method for producing an optoelectronic component.

A component comprising a semiconductor body with which contact is made in planar fashion is known for example from the document DE 103 53 679 A1. In particular, the component comprises a substrate, an optoelectronic semiconductor body arranged thereon, and an insulating layer, wherein the insulating layer is led over the substrate and the optoelectronic semiconductor body. For making contact with the optoelectronic semiconductor body, a planar conductor structure in the form of a metallization is led over the insulating layer to contact locations of the semiconductor body and to a conductor track of the substrate.

In the case of conventional planar contact-making techniques, however, it is necessary to uncover connection regions of the semiconductor body in order to be able to make electrically conductive contact with the semiconductor body by means of the planar conductor structure. In particular, it is necessary in this case to remove the insulating layer in the connection region of the semiconductor body. For this purpose, the conventional planar contact-making technology utilizes a laser ablation process for uncovering the connection regions of the semiconductor body. In this case, it is necessary to remove the insulating layer above the connection region in a manner virtually free of residues. If the insulating layer is not removed in a manner free of residues, this can lead to an impairment, in particular a deterioration, of the power during the operation of the component. Furthermore, a deviation from removal of the insulating layer in a manner free of residues can lead to an increased power input, as a result of which the semiconductor body can disadvantageously be damaged.

The invention is based on the object of providing an improved optoelectronic component which, in particular, has a small structural height and at the same time a reliable operating power and is furthermore distinguished by a simplified production method.

These objects are achieved by means of an optoelectronic component comprising the features of patent claim 1 and a method for producing said component comprising the features of patent claim 9. The dependent claims relate to advantageous embodiments and preferred developments of the component and of the method for producing said component.

The invention provides an optoelectronic component comprising at least one semiconductor body having a radiation exit side. The semiconductor body is arranged by a side lying opposite the radiation exit side on a substrate, wherein at least one electrical connection region is arranged on the radiation exit side. A metallization bump is arranged on the electrical connection region. Furthermore, the semiconductor body is at least partly provided with an insulating layer, wherein the metallization bump projects beyond the insulating layer. At least one planar conductor structure is arranged on the insulating layer for the purpose of making contact with the semiconductor body in planar fashion, said conductor structure being electrically conductively connected to the electrical connection region by means of the metallization bump.

A particularly small structural height of the component advantageously results from making contact with the semiconductor body in planar fashion. A compact component can thus advantageously be provided. A close arrangement of the conductor structures to the semiconductor body is advantageously made possible, thus resulting in a particularly small structural height of the component. In particular, a close arrangement of, for example, optical elements to the semiconductor body is made possible as a result.

Optical elements are, in particular, components which influence the radiation emitted by the semiconductor body in a targeted manner, in particular change the emission characteristic, such as lenses, for example.

By virtue of the metallization bump on the connection region of the semiconductor body, which protrudes from the insulating layer, it is furthermore possible to avoid a laser ablation process of the insulating layer above the electrical connection region of the semiconductor body, as a result of which damage to the connection regions of the semiconductor body can be avoided, in particular prevented. In particular, a homogeneous, disturbance-free connection region surface is thus made possible, as a result of which an influencing of the operating power of the semiconductor body can be prevented. A reliable component can thus advantageously be obtained.

A metallization bump is, for example, an elevation comprising a metallic material. In this case, the metallization bump need not necessarily have a specific form. In particular, the metallization bump projects beyond the insulating layer. By way of example, the metallization bump protrudes from a surface of the insulating layer that lies opposite the semiconductor body. The metallization bump thus has, on the radiation exit side, in particular, a greater height than the insulating layer. The metallization bump preferably penetrates through the insulating layer completely.

Metallization bumps are also known to the person skilled in the art, in particular, as “bumps”.

The metallization bump is, in particular, a component part of the component which is separate from the connection region of the semiconductor body and from the planar conductor structure. Preferably, the metallization bump is adhesively bonded or soldered on to the connection region, for example.

The semiconductor body is preferably a semiconductor chip, particularly preferably a light emitting diode (LED) or a laser diode.

The semiconductor body preferably has a radiation-emitting active layer. The active layer preferably has a pn junction, a double heterostructure, a single quantum well structure (SQW), or a multiquantum well structure (MQW) for generating radiation.

The semiconductor body is preferably based on a nitride, phosphide or arsenide compound semiconductor. Preferably, the semiconductor body is embodied as a thin-film semiconductor body. A thin-film semiconductor body is, in particular, a semiconductor body during whose production the growth substrate has been stripped away.

In a preferred configuration of the optoelectronic component, the metallization bump is a so-called “studbump”. A studbump is, for example, a wire, preferably a pinched-off gold wire (Au wire). The wire is arranged in particular on the connection region of the semiconductor body, which is preferably embodied as a contact-making pad. Studbumps are known to the person skilled in the art and will therefore not be explained in greater detail at this juncture.

In a further preferred configuration of the optoelectronic component, the metallization bump is a so-called “solder ball”, for example a solder globule or a “flip chip bump”. In this case, a solder globule is preferably any metallic body which can be soldered on to the connection region. In particular, a solder globule should be understood to be not only a spherical body, but furthermore any sphere-like body such as, for example, post-type bodies or the like. In this case, bodies having a rounding only on the area facing away from the radiation side are also encompassed by the term solder globule. Cylindrical bodies are also encompassed by the term solder globule in the context of the application. Solder balls, solder globules and flip-chip bumps are known to the person skilled in the art and will therefore not be explained in greater detail at this juncture.

In a preferred configuration of the optoelectronic component, the metallization bump contains a nickel-gold (Ni/Au) compound and/or a nickel-palladium (Ni/Pd) compound.

Preferably, the metallization bump is electrically conductive and connects the electrical connection region of the semiconductor body to the planar conductor structure, such that electrically conductive contact is made with the semiconductor body by means of the metallization bump. The insulating layer preferably has a perforation in the region of the metallization bump, the metallization bump penetrating completely through said perforation.

In a further preferred configuration of the optoelectronic component, the insulating layer is transparent to a radiation emitted by the semiconductor body. Preferably, the insulating layer is at least partly radiation-transmissive to the radiation emitted by the semiconductor body. The radiation emitted by the semiconductor body can thus be coupled out through the insulating layer, without incurring significant optical losses in the process. Absorption of the radiation emitted by the semiconductor body in the insulating layer can thus advantageously be reduced, such that the efficiency of the component is advantageously increased.

The insulating layer is preferably a film, a lacquer or a polymer layer.

In a further preferred configuration of the optoelectronic component, a conversion material is arranged in the insulating layer.

The conversion material in the insulating layer preferably at least partly absorbs radiation emitted by the semiconductor body, and re-emits a secondary radiation in a different wavelength range. As a result, the component emits mixed radiation containing the radiation emitted by the semiconductor body and the secondary radiation of the conversion material. Preferably, it is thus possible to produce, for example, a component which emits mixed radiation in the white color locus, also referred to as chromaticity coordinate.

In a further preferred configuration of the optoelectronic component, at least one further semiconductor body is arranged on the substrate. In particular, the further semiconductor body is arranged in a manner spaced apart laterally from the semiconductor body. The further semiconductor body is preferably embodied like the first semiconductor body. In particular, the further semiconductor body has a radiation exit side, on which is arranged at least one electrical connection region on which a metallization bump is arranged. Furthermore, the further semiconductor body is at least partly provided with an insulating layer, wherein the metallization bump penetrates through, in particular projects beyond, the insulating layer.

Preferably, the semiconductor body and the further semiconductor body are electrically conductively connected to one another by means of a further planar conductor structure.

By virtue of the further planar conductor structure that electrically conductively connects the semiconductor bodies to one another, a compact module can advantageously be provided, in particular, since the semiconductor bodies can be arranged on the substrate in a space-saving manner. The basic area of the component is thus advantageously reduced.

A method according to the invention for producing an optoelectronic module comprises, in particular, the following steps:

a) arranging a semiconductor body by a side facing away from a radiation exit side on a substrate,

b) applying a metallization bump on an electrical connection region of the semiconductor body, which is arranged on the radiation exit side,

c) subsequently applying an insulating layer to the semiconductor body in such a way that the metallization bump projects beyond the insulating layer.

Before the process of applying the insulating layer on the semiconductor body, accordingly, the electrical connection region of the semiconductor body is provided with the metallization bump (“bumps”). The subsequent process of applying the insulating layer, preferably a film, also referred to as foil, is effected such that the metallization bump protrudes from the surface of the insulating layer after the insulating layer has been applied. A laser ablation of the insulating layer above the electrical connection region of the semiconductor body is thus advantageously obviated, as a result of which damage to the connection region of the semiconductor body can advantageously be prevented. In particular, it is thus advantageously possible to obtain a homogeneous, disturbance-free connection region area which preferably does not adversely influence the operating power of the semiconductor body.

In particular, an improved production method can thus be made possible wherein damage to the connection region of the semiconductor body that conventionally occurs at least partly by means of laser ablation processes is prevented. Furthermore, the method according to the invention preferably obviates the method step of uncovering the connection region of the semiconductor body, in particular in removing the insulating layer above the connection region of the semiconductor body, with the result that a simplified production method can be obtained.

The following methods are preferably employed for producing the metallization bumps on the connection region of the semiconductor body:
screen printing method,
reflow method,
solder ball placement.

The metallization bump is preferably a studbump or a solder ball, wherein, by way of example, an adhesive-bonding or a soldering process is employed for applying the metallization bump on the electrical connection region.

By way of example, the following methods are employed for applying the insulating layer on the semiconductor body, the substrate and the metallization bump in such a way that the metallization bump is free of insulating material of the insulating layer:
laminating the insulating layer, in particular a film, with corresponding pressure,
screen printing insulating material with a cutout in the region of the metallization bump,
molding insulating material with or without a cutout in the connection region of the semiconductor body,
pressing the insulating layer onto the metallization bump, such that the metallization bump is pressed through the insulating layer.

The insulating layer is preferably applied in each case such that the metallization bump or bumps is or are free of material of the insulating layer, but the semiconductor body and the substrate are enveloped, in particular covered, by the insulating layer in regions outside the metallization bump.

Should there nevertheless be residues of the insulating layer on the metallization bump after the insulating layer has been applied, then the metallization bump can be uncovered further by means of a stamping process, a grinding process, laser ablation, a plasma process or a flycut process, thereby enabling electrical contact to be made with the semiconductor body by means of the metallization bump. In particular, the insulating layer can thus be opened above the metallization bump in a manner free of residues.

Furthermore, the semiconductor body can have further connection regions on the radiation exit side, on each of which further connection regions a metallization bump is applied, wherein the insulating layer in this case has a respective perforation in regions of the metallization bumps, such that the metallization bumps in each case penetrate completely through the insulating layer.

A component produced by a method of this type accordingly comprises at least one semiconductor body which, apart from regions of the metallization bumps, is preferably completely enveloped by the insulating layer. Furthermore, the method step of applying the insulating layer on the semiconductor body can likewise comprise applying the insulating layer on the substrate in regions of the substrate which are situated outside the mounting region or mounting regions of the semiconductor body.

After the process of applying the insulating layer on the semiconductor body and the substrate, the planar conductor structure or the planar conductor structures, for example in the form of metal structures, is or are furthermore applied. Possible methods for this purpose are known to the person skilled in the art from the document DE 103 53 679 A1 for example, the disclosure content of which is hereby explicitly included in the present application.

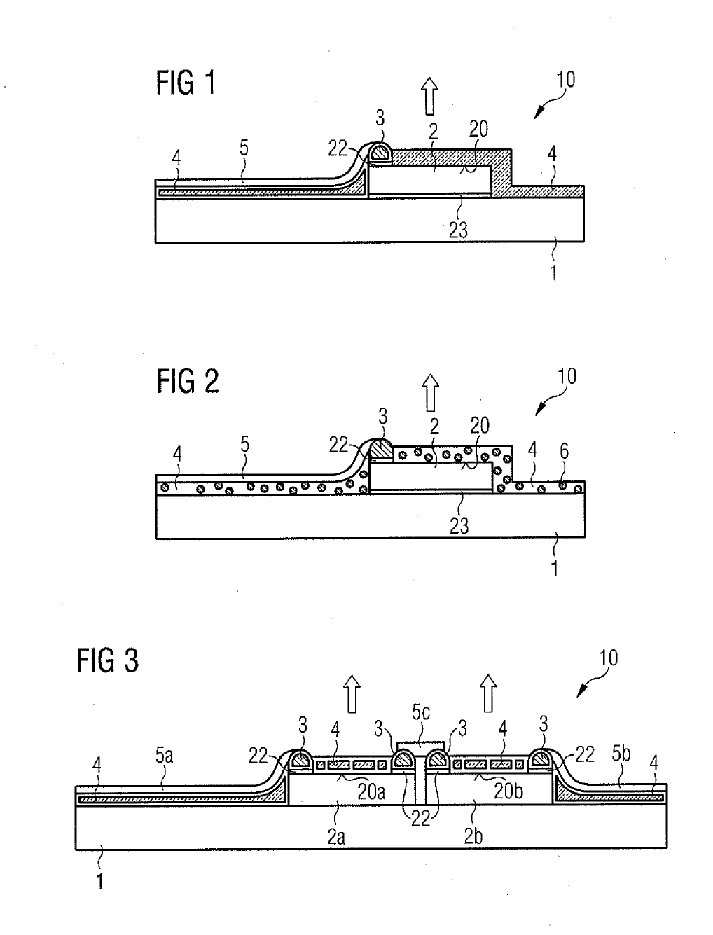

Further features, advantages, preferred configurations and expediencies of the optoelectronic component and of the method for producing said component will become apparent from the exemplary embodiments explained below in conjunction with FIGS. 1 to 3, in which:

FIGS. 1 to 3 each show a schematic cross section of exemplary embodiments of a component according to the invention.

Identical or identically acting constituent parts are in each case provided by the same reference symbols. The illustrated constituent parts and also the size relationships of the constituent parts among one another should not be regarded as true to scale.

FIG. 1 illustrates an optoelectronic component comprising a substrate 1 and a semiconductor body 2 arranged thereon. The semiconductor body 2 preferably has a radiation-emitting active layer for generating electromagnetic radiation. By way of example, the semiconductor body 2 is a semiconductor chip, preferably a light emitting diode (LED) or a laser diode.

In the exemplary embodiment in FIG. 1, the semiconductor body 2 has a contact area 23 on the side facing the substrate 1. In particular, the semiconductor body is electrically conductively contact-connected, by means of the contact area 23, to conductor tracks arranged on the substrate 1 or to the substrate 1, which in this case comprises an electrically conductive material.

A radiation exit side 20 is arranged on that side of the semiconductor body 2 which faces away from the substrate 1. Through the radiation exit side 20, preferably a large part of the radiation emitted by the active layer is coupled out from the semiconductor body 2. The radiation emitted by the semiconductor body 2 is in each case represented by an arrow in exemplary embodiments 1 to 3.

An electrical connection region 22 is arranged on the radiation exit side 20 of the semiconductor body 2. In the exemplary embodiment in FIG. 1, the electrical connection region 22 is arranged in a side region of the radiation exit side 20, such that the electrical connection region need not necessarily be transparent to the radiation emitted by the semiconductor body 2.

A metallization bump 3 is arranged on the electrical connection region 22. The metallization bump 3 can be, for example, a studbump, a solder ball or a solder globule. In particular, the metallization bump comprises an electrically conductive material. The metallization bump 3 is preferably a separate component part of the component. In particular, the metallization bump 3 is separate from the electrical connection region 22 of the semiconductor body 2. The metallization bump 3 preferably contains a nickel-gold compound.

An insulating layer 4 is arranged on the semiconductor body 2, in particular on the radiation exit side 20. The insulating layer 4 is, in particular, also arranged on the substrate 1 in regions surrounding the semiconductor body 2.

Preferably, the insulating layer 4 completely surrounds the semiconductor body 2 apart from the electrical connection region 22. Preferably, the insulating layer is transparent, or at least partly transparent, to the radiation emitted by the semiconductor body 2, such that the radiation emitted by the semiconductor body 2 can be coupled out from the component 10 at the radiation exit side 20.

The metallization bump 3 projects beyond the insulating layer 4. In particular, no insulating layer 4 is arranged in the region of the metallization bump 3. The height of the metallization bump 3 on the radiation exit side 20 is preferably greater than the height of the insulating layer 4 on the radiation exit side 20. In particular, no insulating layer 4, in particular no insulating material of the insulating layer 4, is arranged on the metallization bump 3.

A planar conductor structure 5 is arranged on the insulating layer 4 for the purpose of making contact with the semiconductor body 2 in planar fashion. The planar conductor structure 5 is, in particular, electrically conductively connected to the electrical connection region 22 of the semiconductor body 2 by means of the metallization bump 3. The metallization bump 3 is preferably a component part of the component 10 that is separate from the planar conductor structure 5 and from the connection region 22.

Electrically conductive contact can be made with the semiconductor body 2 preferably by means of the contact area 23 on that side of the semiconductor body 2 which faces the substrate 1, and by means of the electrical connection region 22 via the metallization bump 3 and the planar conductor structure 5.

Since, in the exemplary embodiment in FIG. 1, the electrical connection region 22, the metallization bump 3 and the planar conductor structure 5 are arranged in a side region of the radiation exit side 20 of the semiconductor body 2, the radiation coupling-out of the radiation emitted by the semiconductor body 2 from the component 10 is hardly impaired, in particular reduced, by these component parts. By virtue of the lateral arrangement of the planar contact-making structures and of the metallization bump 3 and of the connection region 22, it is possible to reduce absorption processes which can occur in these component parts of the component, as a result of which the radiation efficiency of the component is advantageously improved.

The exemplary embodiment in FIG. 1 has the advantage, in particular, that the electrical connection region 22 of the semiconductor body 2 has a homogeneous, disturbance-free surface. The homogeneous, disturbance-free surface of the electrical connection region 22 arises by virtue of the fact that a conventional laser ablation process for uncovering the connection region 22 by removing the insulating layer 4 therefrom is not necessary since the electrical connection region 22 is electrically conductively connected to the planar conductor structure 5 by means of the metallization bump 3 having a greater height than the insulating layer 4.

A method for producing an optoelectronic component in accordance with FIG. 1 has the following method steps, in particular:

Arranging the semiconductor body 2 by a side facing away from the radiation exit side 20 on a substrate 1, subsequently applying a metallization bump 3 on an electrical connection region 22 of the semiconductor body 2, which is arranged on the radiation exit side 20, and subsequently applying an insulating layer 4 to the semiconductor body 2 in such a way that the metallization bump 3 projects beyond the insulating layer 4.

A production method of this type has the advantage, in particular, that it is not necessary to uncover the connection region 22 by removing the insulating layer 4 therefrom, since the electrical contact-connection is effected by means of the metallization bump 3 projecting beyond the insulating layer 4. As a result, the connection region 22 is advantageously not damaged by a laser ablation process, for example, with the result that a homogeneous, disturbance-free connection region area is made possible.

In this case, the insulating layer 4 is applied in such a way that the metallization bump 3 projects beyond the surface of the insulating layer 4. In particular, the metallization bump 3 completely penetrates through the insulating layer 4. Such an effect can be made possible, for example, by means of one of the following methods:
laminating the insulating layer 4, in particular a film, with corresponding pressure,
screen printing insulating material with cutouts in the region of the metallization bump 3,
molding insulating material,
pressing the insulating layer 4 onto the component 10 in such a way that the metallization bumps 3 are pressed into the insulating layer 4 in such a way that they preferably completely penetrate through the insulating layer 4.

In a method of this type, after the insulating layer 4 has been applied, the metallization bump 3 is preferably free of insulating material of the insulating layer 4. Should the metallization bump 3 nevertheless not completely penetrate through the insulating layer 4, the insulating material of the insulating layer 4 can be removed without any residues in the region of the metallization bumps 3 by means of, for example, a stamping process, a grinding process, laser ablation, a plasma process or a flycut process.

The metallization bump 3 is applied to the electrical connection region 22 for example by means of a screen printing or reflow method. Alternatively, the metallization bump 3 can be applied to the connection region 22 by means of an adhesive-bonding or soldering process. In this case, the metallization bump 3 is for example a solder ball (“solder ball placement”).

Methods for applying the planar conductor structure 5 to the insulating layer 4 are known to the person skilled in the art from the document DE 103 53 679 A1, for example, and will therefore not be discussed in any greater detail at this juncture.

FIG. 2 shows a further exemplary embodiment of an optoelectronic component according to the invention. The exemplary embodiment in FIG. 2 differs from the exemplary embodiment in FIG. 1 in that a conversion material 6 is arranged in the insulating layer 4. The conversion material 6 absorbs at least part of the radiation emitted by the semiconductor body 2 and re-emits a secondary radiation having a wavelength range different from the wavelength range of the radiation emitted by the semiconductor body 2. A component having mixed radiation comprising the radiation emitted by the semiconductor body 2 and the secondary radiation can advantageously be made possible in this way. By way of example, a component that emits white light can thus be obtained.

For the rest, the exemplary embodiment in FIG. 2 corresponds to the exemplary embodiment in FIG. 1.

FIG. 3 illustrates a further exemplary embodiment of a component according to the invention. In contrast to the exemplary embodiment illustrated in FIG. 1, in the exemplary embodiment in FIG. 3, a further semiconductor body 2b is arranged on the substrate 1. In particular, the semiconductor body 2a and the further semiconductor body 2b are arranged alongside one another. Preferably, the semiconductor bodies 2a, 2b are at a small distance from one another.

The further semiconductor body 2b is preferably configured like the semiconductor body 2a. In particular, the further semiconductor body 2b has a radiation exit side 20b lying opposite the substrate 1. Furthermore, the further semiconductor body 2b has electrical connection regions 22, on each of which a metallization bump 3 is arranged. An insulating layer 4 is arranged on that side of the semiconductor body 2b which faces away from the substrate 1, said insulating layer at least partly enveloping the semiconductor body 2b. The metallization bumps 3 project beyond the insulating layer 4, such that electrical contact can be made with the electrical connection regions 22 by means of the metallization bumps 3.

In contrast to the exemplary embodiment illustrated in FIG. 1, the semiconductor bodies 2a, 2b each have two electrical connection regions 22 on the radiation exit side 20a, 20b, on each of which a metallization bump 3 is arranged. A contact area 23 as illustrated in the exemplary embodiments in FIGS. 1 and 2 for making electrical contact with the semiconductor bodies 2a, 2b is therefore not necessary in the exemplary embodiment in FIG. 3.

The electrical connection regions 22 and the metallization bumps 3 are preferably arranged on opposite sides of the radiation exit side 20a, in particular in each case in the edge region of the radiation exit side 20a, 20b.

The semiconductor body 2a and the further semiconductor body 2b are electrically connected to one another by means of a further planar conductor structure 5c. In particular, one of the metallization bumps 3 of the semiconductor body 2a is in electrical contact with one of the metallization bumps 3 of the further semiconductor body 2b by means of the further planar conductor structure 5c. The metallization bumps 3 which are not electrically conductively connected to respectively the other semiconductor body 2a, 2b are connected to a respective planar conductor structure 5a, 5b, such that the semiconductor bodies 2a, 2b can be electrically contact-connected, in particular electrically connected externally, via the planar conductor structures 5a, 5b, 5c by means of the electrical connection regions 22 and the metallization bumps 3.

The component 10 in FIG. 3 accordingly has a plurality of, in particular two, semiconductor bodies 2a, 2b which are in electrical contact with one another and can be electrically connected externally via planar conductor structures 5a, 5b. By virtue of such contact-making, components 10 can be made possible which have a plurality of semiconductor bodies 2a, 2b at a small distance from one another, with the result that the basic area of such a component 10 is advantageously reduced. Miniaturized components 10 comprising a plurality of semiconductor bodies can thus be realized.

For the rest, the exemplary embodiment in FIG. 3 corresponds to the exemplary embodiment in FIG. 1.

The invention is not restricted to the exemplary embodiments by the description on the basis of said exemplary embodiments, but rather encompasses any novel feature and also any combination of features, which in particular includes any combination of features in the present claims, even if this feature or this combination itself is not explicitly specified in the patent claims or exemplary embodiments.

1. An optoelectronic component comprising at least one semiconductor body having a radiation exit side, said semiconductor body being arranged by a side lying opposite the radiation exit side on a substrate, wherein:
at least one electrical connection region, on which a metallization bump is arranged is arranged on the radiation exit side,
the semiconductor body is at least partly provided with an insulating layer, wherein the metallization bump projects beyond the insulating layer, and
at least one planar conductor structure is arranged on the insulating layer for the purpose of making contact with the semiconductor body in planar fashion, said conductor structure being electrically conductively connected to the electrical connection region by means of the metallization bump.

2. The optoelectronic component according to claim 1, wherein the metallization bump is a studbump.

3. The optoelectronic component according to claim 1, wherein the metallization bump is a solder ball.

4. The optoelectronic component according to claim 1, wherein the metallization bump contains a nickel-gold compound and/or a nickel-palladium compound.

5. The optoelectronic component according to claim 1, wherein the insulating layer is transparent to a radiation emitted by the semiconductor body.

6. The optoelectronic component according to claim 1, wherein conversion material is arranged in the insulating layer.

7. The optoelectronic component according to claim 1, wherein at least one further semiconductor body is arranged on the substrate.

8. The optoelectronic component according to claim 7, wherein the semiconductor body and the further semiconductor body are electrically conductively connected to one another by means of a further planar conductor structure.

9. A method for producing an optoelectronic component comprising the steps of:
A) arranging a semiconductor body by a side facing away from a radiation exit side on a substrate,
B) applying a metallization bump on an electrical connection region of the semiconductor body, which is arranged on the radiation exit side,
C) subsequently applying an insulating layer to the semiconductor body in such a way that the metallization bump projects beyond the insulating layer.

10. The method according to claim 9, wherein method step B) comprises a screen printing method or a reflow method.

11. The method according to claim 9, wherein the metallization bump is a solder ball, wherein method step B) comprises a soldering process.

12. The method according to claim 9, wherein method step C) comprises laminating the insulating layer under pressure.

13. The method according to claim 9, wherein method step C) comprises a screen printing method or a molding method.

14. The method according to claim 9, wherein in method step C), the insulating layer is pressed onto the metallization bumps.

15. The method according to claim 9, wherein method step C) comprises uncovering the metallization bump by means of a stamping process, a grinding process, laser ablation, a plasma process or a flycut process.

16. An optoelectronic component comprising at least one semiconductor body having a radiation exit side, said semiconductor body being arranged by a side lying opposite the radiation exit side on a substrate, wherein:
at least one electrical connection region on which a metallization bump is arranged is arranged on the radiation exit side,
the semiconductor body is at least partly provided with an insulating layer, wherein the metallization bump projects beyond the insulating layer,
at least one planar conductor structure is arranged on the insulating layer for the purpose of making contact with the semiconductor body in planar fashion, said conductor structure being electrically conductively connected to the electrical connection region by means of the metallization bump,
the metallization bump is a solder ball,
the metallization bump contains a nickel-gold compound and/or a nickel-palladium compound, and
the metallization bump is a sphere-like body or a post-type body.
